(19) United States
(12) Patent Application Publication
(10) Pub. No.: US 2025/0191936 A1
(43) Pub. Date: Jun. 12, 2025

(54) PACKAGE STRUCTURE AND PACKGING METHOD

(71) Applicant: Semiconductor Manufacturing International (Shanghai) Corporation, Shanghai (CN)

(72) Inventors: Jisong JIN, Shanghai (CN); Fengping CAI, Shanghai (CN); Xiaoli ZHAO, Shanghai (CN)

(21) Appl. No.: 18/969,802

(22) Filed: Dec. 5, 2024

(30) Foreign Application Priority Data
Dec. 7, 2023 (CN) 202311677092.2

(51) Int. Cl. H01L 21/48; H01L 23/498; H01L 23/538; H01L 25/00; H01L 25/03

(52) U.S. Cl. CPC H01L 21/4846; H01L 23/5385; H01L 23/5386; H01L 25/03; H01L 25/50; H01L 23/498

(57) ABSTRACT

A package structure includes a substrate; a chip bridge including a frontside and a backside that is bonded to the substrate; a redistribution layer bonded to the frontside of the chip bridge and including one or more stacked interconnection layers, an interconnection layer including an interconnect via and an interconnection metal layer on the interconnect via, and the interconnect via being in contact with the chip bridge; solder pads between the frontside of the chip bridge and the substrate and electrically connecting the chip bridge with the redistribution layer; a first chip bonded to the redistribution layer and electrically connected to the chip bridge; and a chip structure bonded to the redistribution layer on a side of the first chip along a lateral direction, the chip structure being electrically connected to the redistribution layer, and also electrically connected to the first chip through the chip bridge.

### CROSS-REFERENCE TO RELATED APPLICATION

This application claims the priority of Chinese Patent Application No. CN 202311677092.2, filed on Dec. 7, 2023, the entire content of which is incorporated herein by reference.

### FIELD OF THE DISCLOSURE

The present disclosure relates to the field of semiconductor manufacturing and, in particular to a package structure and a packaging method.

### BACKGROUND

In conventional chip manufacturing technologies, the size of single chips has been pushed to their limits. However, their applications require the capabilities of large-scale integrated circuits. High-speed and small-volume interconnections between chips become major challenges.

One solution is to use a smaller integrated circuit of a silicon bridge (Si Bridge) chip embedded in a silicon substrate to interconnect chips through the Si Bridge chip, thereby providing heterogeneous chip packaging. This, however, makes packaging structures more complicated.

### SUMMARY OF THE DISCLOSURE

One aspect of the present disclosure includes a package structure. The package structure includes a substrate; a chip bridge including a frontside and a backside that is bonded to the substrate; a redistribution layer bonded to the frontside of the chip bridge and including one or more stacked interconnection layers, an interconnection layer including an interconnect via and an interconnection metal layer on the interconnect via, and the interconnect via being in contact with the chip bridge; solder pads between the frontside of the chip bridge and the substrate and electrically connecting the chip bridge with the redistribution layer; a first chip bonded to the redistribution layer and electrically connected to the redistribution layer and the chip bridge; and a chip structure bonded to the redistribution layer on a side of the first chip along a lateral direction, the chip structure being electrically connected to the redistribution layer, and the chip structure being electrically connected to the first chip through the chip bridge.

Optionally, the package structure further includes interconnection pillars on the substrate at both sides of the chip bridge. The interconnection pillars are electrically connected to the redistribution layer.

Optionally, the package structure further includes a first sealing layer which fills gaps between adjacent interconnect pillars and adjacent solder pads between the substrate and the redistribution layer.

Optionally, the package structure further includes conductive bumps between the redistribution layer and the first chip, and between the redistribution layer and the chip structure, the conductive bumps electrically connecting the first chip with the redistribution layer, and the conductive bumps also electrically connecting the chip structure and the redistribution layer.

Optionally, the package structure further includes a second sealing layer which fills gaps between adjacent conductive bumps and wraps around the conductive bumps.

Optionally, the first chip includes a logic chip, the chip structure includes one or more second chips stacked along a vertical direction, and the second chip includes a memory chip.

Optionally, a thickness of the chip bridge is 2 μm to 100 μm.

Another aspect of the present disclosure includes a packaging method. The method includes bonding a first substrate to a frontside of a chip bridge; bonding a second substrate to a backside of a chip bridge; removing the first substrate to expose the frontside of the chip bridge; forming a redistribution layer on the frontside of the chip bridge; and bonding a chip structure and a first chip on the redistribution layer, the chip structure located on a side of the first chip along a lateral direction and electrically connected to the redistribution layer. The first chip is electrically connected to the redistribution layer, and the first chip is electrically connected to the chip structure through the chip bridge.

Optionally, the packaging method further includes forming solder pads between the frontside of the chip bridge and the first substrate. The redistribution layer is electrically connected to solder pads.

Optionally, before bonding the first substrate to the frontside of the chip bridge, the packaging method further includes forming discrete interconnection pillars on the first substrate on both sides of the chip bridge. When bonding the second substrate to the backside of the chip bridge, the second substrate is also bonded to the interconnection pillars. When forming the redistribution layer on the frontside of the chip bridge, the redistribution layer is also electrically connected to the interconnection pillars.

Optionally, after forming the discrete interconnection pillars on the first substrate on both sides of the chip bridge, before bonding the second substrate to the backside of the chip bridge, the packaging method further includes: forming a first sealing layer on the first substrate, the first sealing layer filling gaps between adjacent interconnection pillars and adjacent solder pads, and the first sealing layer exposing a top of the interconnection pillars.

Optionally, when bonding the second substrate to the backside of the chip bridge, the second substrate is also bonded to the first sealing layer; and when forming the redistribution layer on the frontside of the chip bridge, the redistribution layer covers the first sealing layer.

Optionally, forming the first sealing layer on the first substrate includes forming a first sealing material layer on the first substrate to fill the gaps between the adjacent interconnection pillars and the adjacent solder pads, the first sealing material layer covering the interconnection pillars and the chip bridge; and planarizing the first sealing material layer until the top of the interconnection pillar is exposed to form the first sealing layer.

Optionally, the redistribution layer includes one or more stacked interconnection layers, an interconnection layer includes an interconnect via and an interconnection metal layer on the interconnect via, and the interconnect via is in contact with the chip bridge.

Optionally, bonding the chip structure and the first chip on the redistribution layer includes: forming conductive bumps on the redistribution layer; or on both the first chip and the chip structure; and bonding the chip structure and the first chip to the redistribution layer using the conductive bumps.

### BRIEF DESCRIPTION OF THE DRAWINGS

The following drawings are merely examples for illustrative purposes according to various disclosed embodiments and are not intended to limit the scope of the present disclosure.

FIGS. 1-3 are schematic structural diagrams corresponding to a packaging method.

FIG. 4 is a schematic structural diagram of an exemplary package structure according to various embodiments of the present disclosure.

FIGS. 5-12 are schematic structural diagrams at various stages of an exemplary packaging method for forming a package structure according to various embodiments of the present disclosure.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

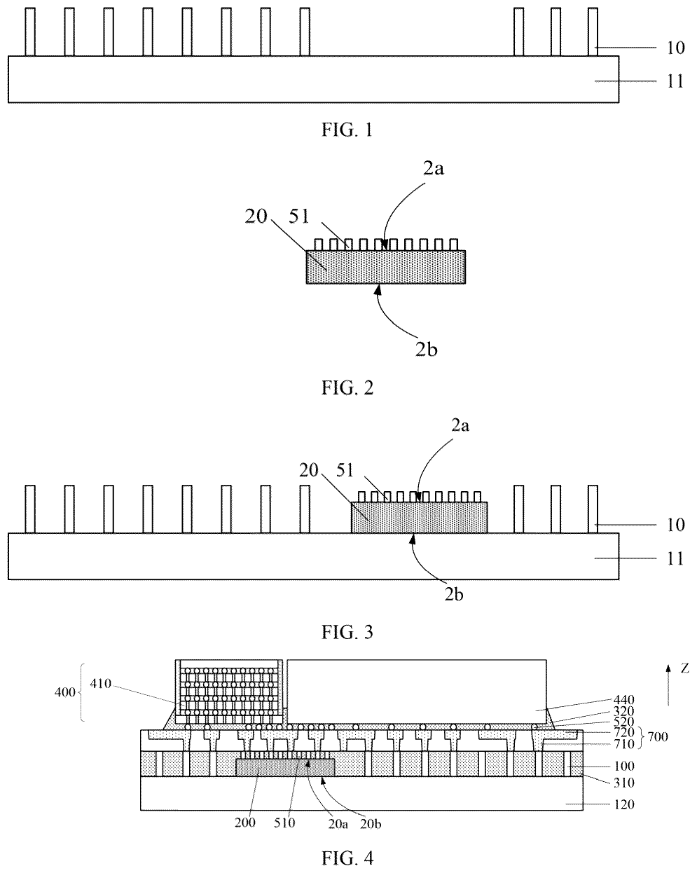

Current packaging methods are difficult and complicated to operate. FIGS. 1-3 are schematic structural diagrams corresponding to a packaging method.

Referring to FIG. 1, a substrate 11 is provided. The substrate 11 includes a bonding area for bonding a chip. An interconnection pillar 10 is formed on the substrate 11 at a side of the bonding area.

Referring to FIG. 2, a chip bridge 20 is provided, including a frontside 2a and a backside 2b opposite to the frontside 2a. Discrete conductive bumps 51 are formed on the frontside 2a of the chip bridge 20.

Referring to FIG. 3, the backside 2b of the chip bridge 20 is bonded to the substrate 11.

Since the conductive bumps 51 cause the frontside 2a to be uneven, when the backside 2b of the chip bridge 20 is bonded to the substrate 11, the conductive bumps 51 on the frontside 2a lead difficulty in directly lifting the chip bridge 20. As a result, it is difficult and complicated to lift the chip bridge with the backside 2b facing downward, in order to bond the substrate 11.

The present disclosure provides a packaging method. The method includes bonding a first substrate to a frontside (e.g., frontside surface) of a chip bridge; bonding a second substrate to a backside (e.g., backside surface) of a chip bridge; removing the first substrate to expose the frontside of the chip bridge; forming a redistribution layer on the frontside of the chip bridge; and bonding a chip structure and a first chip on the redistribution layer, the chip structure located on a side of the first chip along a lateral direction and electrically connected to the redistribution layer. The first chip is electrically connected to the redistribution layer, and the first chip is electrically connected to the chip structure through the chip bridge.

As disclosed, a conductive bump is formed on the frontside of the chip bridge to realize electrical connection between the chip bridge and the redistribution layer. Compared with a solution in which the conductive bump is formed on the frontside of the chip bridge and then the backside of the chip bridge is bonded to the second substrate, since the conductive bump causes unevenness on the frontside of the chip bridge, it is difficult to lift the chip bridge and bond the chip bridge to the second substrate with the backside of the chip bridge facing down. According to the embodiments of the present disclosure, the frontside of the chip bridge is bonded to the first substrate and the second substrate is bonded to the backside of the chip bridge. This can avoid the process of lifting the chip bridge with an uneven frontside of the chip bridge, making it easy to bond the backside of the chip bridge to the second substrate, and making the packaging method simple and easy to operate.

To make the above-mentioned objects, features, and advantages of the present disclosure more obvious and easier to understand, specific embodiments of the present disclosure are described in detail below with reference to the accompanying drawings.

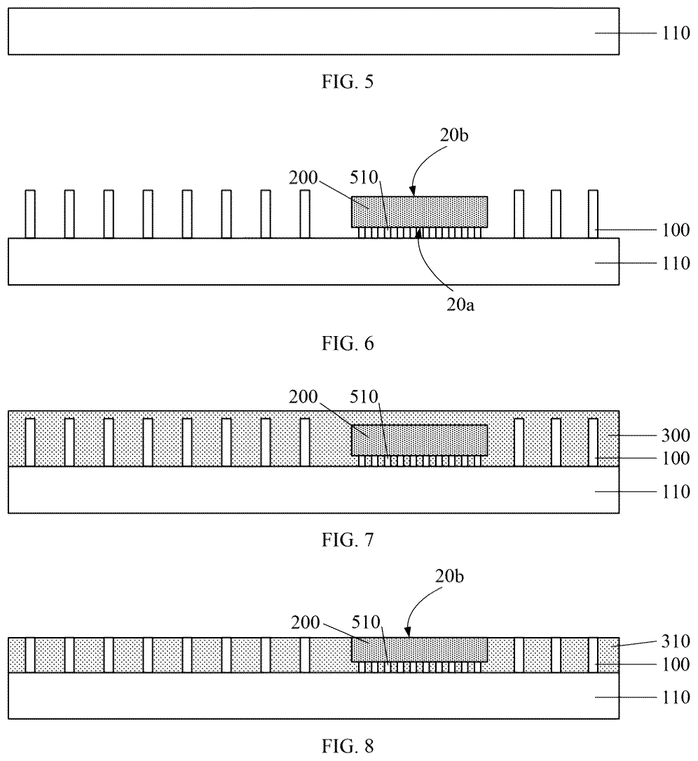

FIG. 4 is a schematic structural diagram of the embodiment of a package structure of the present disclosure.

The package structure includes: a substrate 120; a chip bridge 200, including a frontside 20a and a backside 20b opposite to each other, the backside 20b of the chip bridge 200 facing the substrate 120 and being bonded to the substrate 120; a redistribution layer 700, bonded to the frontside 20a of the chip bridge 200, the redistribution layer 700 including one or more stacked interconnection layers, each interconnection layer including an interconnect via 710 and an interconnection metal layer 720 located on the interconnect via 710, the chip bridge 200 being connected to the interconnect via 710 for connection; solder pads 510, located between the frontside 20a and the substrate 120 and electrically connecting the chip bridge 200 and the redistribution layer 700; a first chip 440, bonded to the redistribution layer 700 and electrically connected to the redistribution layer 700 and the chip bridge 200; and a chip structure 400, bonded to the redistribution layer 700 on the side of the first chip 440 along a lateral direction and electrically connected to the redistribution layer 700, and further electrically connected to the first chip 440 through the chip bridge 200.

The substrate 120 is used to provide a process operation basis for bonding the chip bridge 200 and the redistribution layer 700.

In one embodiment, the material of the substrate 120 is silicon.

In one embodiment, the substrate 120 is a carrier substrate.

In one embodiment, the substrate 120 is a wafer. In another embodiment, the substrate may also be a glass substrate.

The chip bridge (e.g., “bridge die”) 200 is used to realize electrical connection between the chip structure 400 and the first chip 440.

The chip bridge 200 includes a frontside 20a and a backside 20b opposite to the frontside 20a. The frontside 20a is used to realize electrical connection between the chip bridge 200 and the outside. The backside 20b is used to be attached to and bonded with the substrate 120.

In one embodiment, a circuit structure is formed in the chip bridge 200. The first chip 440 is electrically connected to the chip structure 400 via the circuit structure.

In one embodiment, the chip bridge 200 includes a silicon bridge (Si bridge) or an interposer.

It should be noted that, the thickness of the chip bridge 200 should be neither too large nor too small. If the thickness of the chip bridge 200 is too large, it is easy to cause the thickness of the interconnection structure to be too large, which is not conducive to improving the integration of the package structure. If the thickness of the chip bridge 200 is too small, it is easy to affect the formation of the circuit structure in the chip bridge 200 and affect the electrical connection performance of the chip bridge 200. For this reason, the thickness of the chip bridge 200 is 2 μm to 100 μm.

The redistribution layer 700 is used to achieve bonding with the chip bridge 200, thereby achieving electrical connection between the redistribution layer 700 and the chip bridge 200. The redistribution layer 700 is also used to achieve bonding with the chip structure 400 and the first chip 440, thereby achieving electrical connection between the redistribution layer 700 and the chip structure 400, and the first chip 440.

The first chip 440 is used to be electrically connected to the redistribution layer 700 to achieve electrical connection between the first chip 440 and the outside in the vertical direction. Correspondingly, the first chip 440 is electrically connected to the chip bridge 200 through the redistribution layer 700 to achieve electrical connection between the first chip 440 and the chip structure 400 through the chip bridge 200.

In one embodiment, the package structure includes a plurality of chip structures 400. The first chip 440 is electrically connected to the redistribution layer 700, and further electrically connected to plurality of chip structures 400 through the chip bridge 200.

In one embodiment, the first chip 440 is a logic chip, for example, including a first logic chip, configured to control, e.g., a memory chip of the chip structures 400. The first logic chip can be a central processing unit (CPU) chip, a graphics processing unit (GPU) chip, or a system on chip (SoC).

The chip structure 400 is electrically connected to the redistribution layer 700, to achieve an electrical connection between the chip structure 400 and the outside in a vertical direction. Correspondingly, the chip structure 400 is electrically connected to the chip bridge 200 through the redistribution layer 700. The chip structure 400 is electrically connected to the first chip 440 through the chip bridge 200.

In one embodiment, the chip structure 400 includes one or more second chips 410 stacked in the vertical direction (as shown in the Z direction in FIG. 4), thereby realizing electrical connection between each second chip 410 and the first chip 440, and electrical connection between each second chip 410 and the external connection in the vertical direction.

In one embodiment, the chip structure 400 is electrically connected to the redistribution layer 700, and is electrically connected to the first chip 440 through the chip bridge 200.

In one embodiment, in the chip structure 400, a high bandwidth memory (HBM) structure composed of a plurality of second chips 410 stacked in the vertical direction is conducive to meet the requirements for higher information transmission speed by adopting the HBM structure.

Among them, the second chip 410 includes a bottom chip located at the bottom and a top chip stacked on the bottom chip. The number of the top chips can be one or more. In one embodiment, the number of top chips is four as an example for explanation. In other embodiments, the number of top chips can also be other numbers.

In one embodiment, the top chip is a memory chip. In a specific implementation, the top chip is an HBM chip.

In one embodiment, the bottom chip is a second logic chip. Specifically, the bottom chip is used as a logic control chip in the chip structure 400.

In one embodiment, the bottom chip and the substrate 120, as well as the adjacent second chips 410 in the vertical direction are electrically connected, thereby achieving electrical integration between the second chips 410 and achieving electrical integration between the second chips 410 and the substrate 120.

In one embodiment, the number of chip structures 400 is plural. A plurality of chip structures 400 is electrically connected to the first chip 440, which is conducive to increasing the memory of the package structure, improving the chip speed, and reducing the chip power consumption.

Solder pads 510 are used to realize the electrical connection between the chip bridge 200 and the redistribution layer 700.

In one embodiment, solder pads 510 is used to realize the electrical connection between the chip bridge 200 and the substrate 700. Generally, solder pads 510 have a thin thickness. Compared with the use of bumps to realize the electrical connection between the chip bridge and the substrate, it is beneficial for reducing the height difference between the chip bridge 200 and the substrate 700, thereby reducing the overall height of the package structure, and further improving the package integration of the package structure.

In one embodiment, the material of solder pads 510 includes one or more of tin, copper, aluminum, tungsten, cobalt, nickel, titanium, tantalum, titanium nitride and tantalum nitride. As an example, the material of solder pads 510 is tin.

In one embodiment, the package structure further includes interconnection pillars 100. The interconnection pillars 100 are formed on the substrate 120 at both sides of the chip bridge 200. The interconnection pillars 100 are electrically connected to the redistribution layer 700.

The interconnection pillar 100 is used to electrically connect with the redistribution layer 700, and correspondingly electrically connect with the first chip 440 and the chip structure 400. Thus, the electrical connection between the first chip 440 and the outside in the vertical direction is realized. The electrical connection between the chip structure 400 and the outside in the vertical direction through the interconnection pillar 100 is realized.

In one embodiment, the interconnect pillar 100 is a copper pillar. Accordingly, the material of the interconnect pillar 100 is copper.

In one embodiment, the package structure further includes: a first sealing layer 310. The first sealing layer fills the gaps between adjacent interconnect pillars 100. The interconnect pillars are located between the substrate 120 and the redistribution layer 700. The first sealing layer fills the gaps between adjacent solder pads 510.

The first sealing layer 310 is used to achieve sealing between the chip bridge 200 and the redistribution layer 700, to achieve sealing between adjacent interconnect pillars 100, and to achieve sealing of adjacent solder pads 510.

In one embodiment, the package structure further includes: a conductive bump 520 located between the redistribution layer 700 and the first chip 440, and between the redistribution layer 700 and the chip structure 400. The conductive bump 520 electrically connects the first chip 440 and the redistribution layer 700. The conductive bump 520 also electrically connects the chip structure 400 and the redistribution layer 700.

The conductive bump 520 is used to realize the electrical connection between the first chip 440 and the redistribution layer 700, and the electrical connection between the chip structure 400 and the redistribution layer 700.

In one embodiment, the material of the conductive bump 520 includes one or more of tin, copper, aluminum, tungsten, cobalt, nickel, titanium, tantalum, titanium nitride, and/or tantalum nitride. As an example, the material of the conductive bump 520 is tin.

In one embodiment, the conductive bump 520 may be microbump (uBump), which has a high density and is conducive to improving the communication speed between the first chip 440 and the redistribution layer 700, and between the chip structure 400 and the redistribution layer 700.

In one embodiment, the package structure further includes: a second sealing layer 320, which is filled between adjacent conductive bumps 520 and in the gaps between adjacent conductive bumps 520. A second sealing layer 320 covers the conductive bumps 520.

The second sealing layer 320 is used to achieve sealing between the first chip 440 and the redistribution layer 700, to achieve sealing between the chip structure 400 and the redistribution layer 700, and to achieve sealing of adjacent conductive bumps 520.

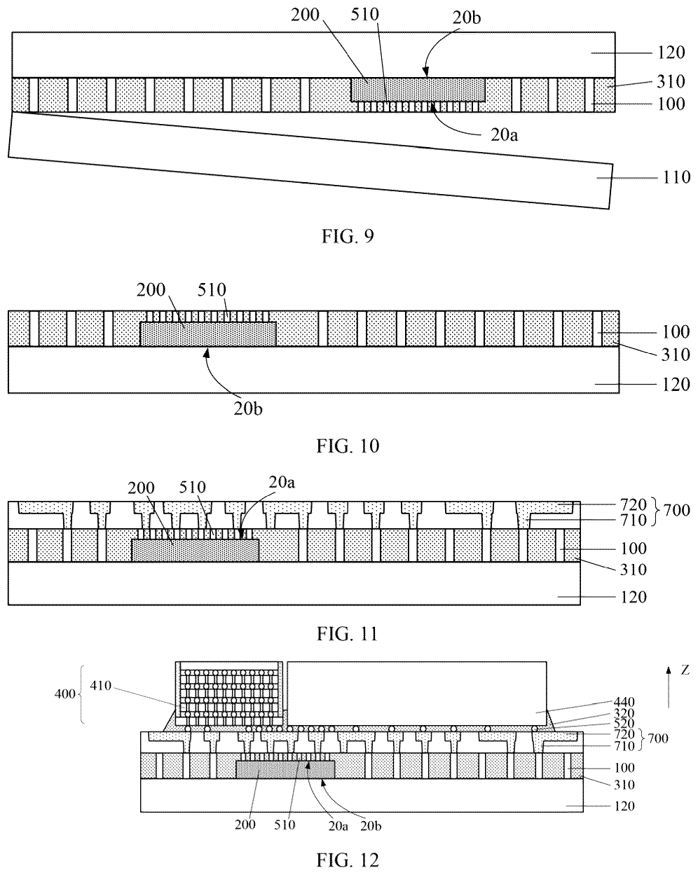

FIGS. 5-12 are schematic diagrams of structures corresponding to each step in the embodiment of the packaging method of the present disclosure.

Referring to FIG. 5, a first substrate 110 is provided.

The first substrate 110 is used to provide a process operation basis for the subsequent sealing of the chip bridge and the interconnection pillar.

In one embodiment, the material of the first substrate 110 is silicon.

In one embodiment, the first substrate 110 is a carrier substrate.

In one embodiment, the first substrate 110 is a wafer. In other embodiments, the first substrate may also be a glass substrate.

Referring to FIG. 6, a chip bridge 200 is provided, including a frontside 20a and a backside 20b.

The chip bridge (bridge die) 200 is used to subsequently realize the electrical connection between the chip structure and the first chip.

The chip bridge 200 includes a frontside 20a and a backside 20b on opposite sides. The frontside 20a is used to realize the electrical connection between the chip bridge 200 and the outside, and the backside 20b is used to bond with the second substrate later.

In one embodiment, a circuit structure is formed in the chip bridge 200, so that the subsequent first chip and the chip structure are electrically connected through the circuit structure.

In one embodiment, the chip bridge 200 includes a silicon bridge (Si bridge) or an interposer.

It should be noted that, the thickness of the chip bridge 200 should be neither too large nor small. If the thickness of the chip bridge 200 is too large, it is easy to cause the thickness of the interconnection structure to be too large, which is not conducive to improving the integration of the package structure. If the thickness of the chip bridge 200 is too small, it is easy to affect the formation of the circuit structure in the chip bridge 200 and the electrical connection performance of the chip bridge 200. In one embodiment, the thickness of the chip bridge 200 is 2 μm to 100 μm.

Still referring to FIG. 6, the first substrate 110 is bonded to the frontside 20a of the chip bridge 200.

The chip bridge 200 is bonded to the first substrate 120. The backside 20b of the chip bridge 200 is exposed, so as to prepare for the subsequent bonding of the second substrate on the backside 20b.

In one embodiment, in the step of bonding the chip bridge 200 to the first substrate 110, solder pads 510 are formed between the frontside 20a and the first substrate 110.

Solder pads 510 is used to subsequently realize the electrical connection between the chip bridge 200 and the redistribution layer.

In one embodiment, the material of solder pads 510 includes one or more of tin, copper, aluminum, tungsten, cobalt, nickel, titanium, tantalum, titanium nitride and tantalum nitride. As an example, the material of solder pads 510 is tin.

In one embodiment, before bonding the first substrate 110 to the frontside 20a of the chip bridge 200, the packaging method further includes: forming discrete interconnection pillars 100 on the first substrate 110 on both sides of the chip bridge 200.

The interconnection pillar 100 is used to be electrically connected to the redistribution layer later, and correspondingly to be electrically connected to the first chip and the chip structure later, so as to realize the electrical connection between the first chip and the outside in the vertical direction and realize the electrical connection between the chip structure and the outside in the vertical direction through the interconnection pillar 100.

In one embodiment, the interconnection pillar 100 is a copper pillar, that is, the material of the interconnection pillar 100 is copper.

With reference to FIGS. 7 and 8, after forming discrete interconnection pillars 100 on the first substrate 110 on both sides of the chip bridge 200, before subsequently bonding the second substrate to the backside 20b of the chip bridge 200, the packaging method further includes: forming a first sealing layer 310 on the first substrate 110, the first sealing layer 310 filling the gaps between adjacent interconnection pillars 100 and between adjacent solder pads 510, and the first sealing layer 310 exposing the top of the interconnection pillars 100.

The first sealing layer 310 is used to achieve sealing between the chip bridge 200 and the subsequent redistribution layer, to achieve sealing between adjacent interconnection pillars 100, and to achieve sealing of adjacent solder pads 510.

In one embodiment, the step of forming the first sealing layer 310 on the first substrate 110 includes: referring to FIG. 7, forming a first sealing material layer 300 filling the gaps between adjacent interconnection pillars 100 and adjacent solder pads 510 on the first substrate 110, and the first sealing material layer 300 covers the interconnection pillars 100 and the chip bridge 200.

The first sealing material layer 300 is used to directly form the first sealing layer 310.

Referring to FIG. 8, the first sealing material layer 300 is planarized until the top of the interconnection pillar 100 is exposed.

The first sealing material layer 300 is planarized to obtain a top surface with good flatness, providing a good process platform for subsequent bonding of the second substrate. The first sealing layer 310 exposes the top of the interconnection pillars 100, preparing for the subsequent electrical connection between the interconnection pillars 100 and the redistribution layer.

It should be noted that in the step of planarizing the first sealing material layer 300, the chip bridge 200 is also thinned on the backside, and a portion of the thickness of the chip bridge 200 is removed along the backside 20b of the chip to obtain a chip bridge 200 with a smaller thickness. This is beneficial for reducing the height difference caused by the introduction of the chip bridge 200 and further reducing the occupied volume of the chip bridge 200.

Referring to FIG. 9, the second substrate 120 is bonded to the backside surface 20b of the chip bridge 200. The backside surface 20b of the chip bridge 200 is opposite to the frontside surface 20a.

The second substrate 120 is used to provide a process operation basis for the subsequent bonding of the chip bridge and the redistribution layer.

In one embodiment, the material of the second substrate 120 is silicon.

In one embodiment, the second substrate 120 is a carrier substrate.

In one embodiment, the second substrate 120 is a wafer. In other embodiments, the first substrate may also be a glass substrate.

The second substrate 120 is bonded to the backside 20b of the chip bridge 200 to prepare for the subsequent removal of the first substrate 110.

Accordingly, in the present embodiment, in the step of bonding the second substrate 120 to the backside 20b of the chip bridge 200, the second substrate 120 is also bonded to the interconnection pillar 100.

In one embodiment, in the step of bonding the second substrate 120 to the backside 20b of the chip bridge 200, the second substrate 120 is also bonded to the first sealing layer 310.

Referring to FIGS. 9 and 10, the first substrate 110 is removed to expose the frontside 20a of the chip bridge 200.

The frontside 20a of the chip bridge 200 is exposed to prepare for the subsequent formation of the redistribution layer on the frontside 200a of the chip bridge 200.

It should be noted that, referring to FIG. 10, In one embodiment, after removing the first substrate 110, the exposed first sealing layer 310 is appropriately planarized so that solder pads 510 and the interconnection pillar 100 are better exposed. That is conducive to improving the electrical connection performance between the subsequent chip bridge 200 and the interconnection pillar 100 and the redistribution layer.

Referring to FIG. 11, the redistribution layer 700 is formed on the frontside 200a of the chip.

The redistribution layer 700 is used to bond with the chip bridge 200, thereby realizing the electrical connection between the redistribution layer 700 and the chip bridge 200. The redistribution layer 700 is also used to bond with the chip structure and the first chip, thereby realizing the electrical connection between the redistribution layer 700 and the chip structure and the first chip.

In one embodiment, the frontside 20a of the chip bridge 200 is formed with the conductive bump to realize the electrical connection between the chip bridge 200 and the redistribution 700. Compared with the scheme of forming the conductive bump on the frontside of the chip bridge and then bonding the backside of the chip bridge to the second substrate, it is difficult to lift the chip bridge and bond it to the second substrate with the backside facing down due to the unevenness of the frontside caused by the conductive bump. In one embodiment, the frontside 20a of the chip bridge 200 is first bonded to the first substrate 110, and then the second substrate 120 is bonded to the backside 20b of the chip bridge 200, thereby avoiding the step of lifting the chip bridge 200 with the uneven frontside 20a, making it easy to bond the backside 20b of the chip bridge 200 to the second substrate 120, thereby making the packaging method simple and easy to operate.

In one embodiment, after the chip bridge 200 is bonded on the second substrate 120, the redistribution layer 700 is bonded on the chip bridge 200. In one embodiment, in the step of forming the redistribution layer 700 on the frontside 200a, the redistribution layer 700 includes one or more stacked interconnection layers. The interconnection layer includes an interconnect via 710 and an interconnection metal layer 720 located on the interconnect via 710. The chip bridge 200 is in contact with the interconnect via 710.

In one embodiment, in the step of forming the redistribution layer 700 on the frontside 200a of the chip, the redistribution layer 700 is electrically connected to solder pads 510. Accordingly, the electrical connection between the redistribution layer 700 and the chip bridge 200 is realized through solder pads 510.

In one embodiment, in the step of forming the redistribution layer 700 on the frontside 200a of the chip, the redistribution layer 700 is also electrically connected to the interconnection pillar 100. The electrical connection between the redistribution layer 700 and the outside in the vertical direction is realized through the interconnection pillar 100.

Accordingly, In one embodiment, in the step of forming the redistribution layer 700 on the frontside 200a of the chip, the redistribution layer 700 covers the first sealing layer 310.

Referring to FIG. 12, the chip structure 400 and the first chip 440 are bonded on the redistribution layer 700. The chip structure 400 is located on the side of the first chip 440. The chip structure 440 is electrically connected to the redistribution layer 700. The first chip 440 is electrically connected to the redistribution layer 700. The first chip 440 is electrically connected to the chip structure 400 through the chip bridge 200.

The first chip 440 is used to be electrically connected to the redistribution layer 700 to realize the electrical connection of the first chip 440 with the outside in the vertical direction. The corresponding first chip 440 is electrically connected to the chip bridge 200 through the redistribution layer 700. The electrical connection between the first chip 440 and the chip structure 400 is realized through the chip bridge 200. The first chip 440 and the chip structure 400 are used to form an integrated package structure.

In one embodiment, the package structure includes multiple chip structures 400. The first chip 440 is electrically connected to the redistribution layer 700, and then electrically connected to each chip structure 400 through the chip bridge 200.

In one embodiment, the first chip 440 is the logic chip, for example, including a first logic chip, used to control the memory chip of the chip structure 400. Specifically, the first logic chip can be a CPU chip, a graphics processing unit (GPU) chip, or an SoC.

The chip structure 400 is used to electrically connect with the redistribution layer 700 to realize the electrical connection between the chip structure 400 and the outside in the vertical direction. The corresponding chip structure 400 is electrically connected to the chip bridge 200 through the redistribution layer 700. The chip structure 400 is electrically connected to the first chip 440 through the chip bridge 200.

In one embodiment, the chip structure 400 includes one or more second chips 410 stacked in the vertical direction (as shown in the Z direction in FIG. 12), so as to realize the electrical connection between each second chip 410 and the first chip 440, and the electrical connection between each second chip 410 and the outside in the vertical direction.

In one embodiment, the chip structure 400 is electrically connected to the redistribution layer 700, and is electrically connected to the first chip 440 through the chip bridge 200.

In one embodiment, in the chip structure 400, the HBM structure composed of multiple second chips 410 stacked in the vertical direction is conducive to meeting the requirements for higher information transmission speed by adopting the HBM structure.

Among them, the second chip 410 includes the bottom chip located at the bottom and the top chip stacked on the bottom chip. The number of top chips can be one or more. In one embodiment, the number of top chips is four as an example for explanation. In other embodiments, the top chips can also be other numbers.

In one embodiment, the top chip is the memory chip. In a specific implementation, the top chip is an HBM chip.

In one embodiment, the bottom chip is the second logic chip. Specifically, the bottom chip is used as the logic control chip in the chip structure 400.

In one embodiment, the bottom chip is electrically connected to the substrate 120, and the adjacent second chips 410 in the vertical direction are electrically connected, so as to realize the electrical integration between the second chips 410, and the electrical integration between the second chip 410 and the substrate 120.

In one embodiment, the number of chip structures 400 is multiple, and multiple chip structures 400 are electrically connected to the first chip 440, which is conducive to increasing the memory of the package structure, improving the chip speed, and reducing the chip power consumption.

In one embodiment, the step of bonding the chip structure 400 and the first chip 440 on the redistribution layer 700 includes: forming the conductive bumps 520 on the redistribution layer 700; or, forming the conductive bumps 520 on the first chip 440 and the chip structure 400.

The conductive bumps 520 are used to realize electrical connection between the first chip 440 and the redistribution layer 700, and between the chip structure 400 and the redistribution layer 700.

In one embodiment, the material of the conductive bump 520 includes one or more of tin, copper, aluminum, tungsten, cobalt, nickel, titanium, tantalum, titanium nitride, and/or tantalum nitride. As an example, the material of the conductive bump 520 is tin.

In one embodiment, the conductive bump 520 may be uBump, which has a high density and is conducive to improving the communication speed between the first chip 440 and the redistribution layer 700, and between the chip structure 400 and the redistribution layer 700.

In one embodiment, the chip structure 400 and the first chip 440 are bonded to the redistribution layer 700 using the conductive bumps 520.

In one embodiment, the packaging method further includes: forming the second sealing layer 320 filled between adjacent conductive bumps 520 and in the gaps between adjacent conductive bumps 520. The second sealing layer 320 covers around the conductive bumps 520.

The second sealing layer 320 is used to achieve sealing between the first chip 440 and the redistribution layer 700, to achieve sealing between the chip structure 400 and the redistribution layer 700, and to achieve sealing between adjacent conductive bumps 520.

As disclosed, the technical solutions of the embodiment of the present disclosure provide the following advantages.

The embodiment of the present disclosure provides a package structure, the chip bridge includes a frontside and a backside, the backside of the chip bridge faces the substrate and is bonded to the substrate, solder pads are located between the frontside and the substrate, and solder pads electrically connect the chip bridge with the redistribution layer. The embodiment of the present disclosure uses solder pads to achieve electrical connection between the chip bridge and the substrate. The solder pads can be made having a thin thickness, compared with using a bump to achieve electrical connection between the chip bridge and the substrate. It is beneficial for reducing the height difference between the chip bridge and the substrate, thereby reducing the overall height of the package structure, and further improving the packaging integration of the package structure.

The embodiment of the present disclosure provides the packaging method. The method includes bonding a first substrate to a frontside of a chip bridge; bonding a second substrate to a backside of a chip bridge; removing the first substrate to expose the frontside of the chip bridge; forming a redistribution layer on the frontside of the chip bridge; and bonding a chip structure and a first chip on the redistribution layer, the chip structure located on a side of the first chip along a lateral direction and electrically connected to the redistribution layer. The first chip is electrically connected to the redistribution layer, and the first chip is electrically connected to the chip structure through the chip bridge.

As disclosed, the conductive bump is formed on the frontside of the chip bridge to realize the connection between the chip bridge and the redistribution layer. The electrical connection of the wiring layer is compared with the solution of forming the conductive bump on the frontside of the chip bridge and then bonding the backside of the chip bridge to the second substrate. Since the conductive bump causes the unevenness of the frontside of the chip bridge, it is more difficult to lift the chip bridge and bond it to the second substrate with the backside of the chip bridge facing down. In the embodiment of the present disclosure, the frontside of the chip bridge is first bonded to the first substrate, and then the second substrate is bonded to the backside of the chip bridge. This can avoid the process of lifting the chip bridge with the uneven frontside of the chip bridge, making it easy to bond the backside of the chip bridge to the second substrate, and making the packaging method simple and easy to operate.

The embodiments disclosed herein are exemplary only. Other applications. advantages, alternations, modifications, or equivalents to the disclosed embodiments are obvious to those skilled in the art and are intended to be encompassed within the scope of the present disclosure.

What is claimed is:

1. A package structure, comprising:
a substrate;
a chip bridge comprising a frontside and a backside, the backside of the chip bridge being bonded to the substrate;
a redistribution layer bonded to the frontside of the chip bridge, the redistribution layer comprising one or more stacked interconnection layers, an interconnection layer comprising an interconnect via and an interconnection metal layer located on the interconnect via, and the interconnect via being in contact with the chip bridge;
solder pads between the frontside of the chip bridge and the substrate, the solder pads electrically connecting the chip bridge with the redistribution layer;
a first chip bonded to the redistribution layer, the first chip being electrically connected to the redistribution layer and the chip bridge; and
a chip structure bonded to the redistribution layer on a side of the first chip, the chip structure being electrically connected to the redistribution layer, and the chip structure being electrically connected to the first chip through the chip bridge.

2. The package structure according to claim 1, further comprising: interconnection pillars on the substrate at both sides of the chip bridge, wherein the interconnection pillars are electrically connected to the redistribution layer.

3. The package structure according to claim 2, further comprising: a first sealing layer which fills gaps between adjacent interconnect pillars and adjacent solder pads between the substrate and the redistribution layer.

4. The package structure according to claim 1, further comprising conductive bumps between the redistribution layer and the first chip, and between the redistribution layer and the chip structure, the conductive bumps electrically connecting the first chip and the redistribution layer, and the conductive bumps also electrically connecting the chip structure and the redistribution layer.

5. The package structure according to claim 4, further comprising a second sealing layer which fills gaps between adjacent conductive bumps and covers around the conductive bumps.

6. The package structure according to claim 1, wherein the first chip includes a logic chip, the chip structure includes one or more second chips stacked along a vertical direction, and the second chip includes a memory chip.

7. The package structure according to claim 1, wherein a thickness of the chip bridge is 2 μm to 100 μm.

8. A packaging method, comprising:
bonding a first substrate to a frontside of a chip bridge;
bonding a second substrate to a backside of the chip bridge;
removing the first substrate to expose the frontside of the chip bridge;
forming a redistribution layer on the frontside of the chip bridge; and
bonding a chip structure and a first chip on the redistribution layer, wherein the chip structure is located on a side of the first chip, the chip structure is electrically connected to the redistribution layer, the first chip is electrically connected to the redistribution layer, and the first chip is electrically connected to the chip structure through the chip bridge.

9. The packaging method according to claim 8, further comprising:
forming solder pads between the frontside of the chip bridge and the first substrate, wherein the redistribution layer is electrically connected to solder pads.

10. The packaging method according to claim 9, wherein before bonding the first substrate to the frontside of the chip bridge, the packaging method further comprises:
forming discrete interconnection pillars on the first substrate on both sides of the chip bridge; wherein when bonding the second substrate to the backside of the chip bridge, the second substrate is also bonded to the interconnection pillars; and when forming the redistribution layer on the frontside of the chip bridge, the redistribution layer is also electrically connected to the interconnection pillars.

11. The packaging method according to claim 10, wherein after forming the discrete interconnection pillars on the first substrate on both sides of the chip bridge, before bonding the second substrate to the backside of the chip bridge, the packaging method further comprises:
forming a first sealing layer on the first substrate, the first sealing layer filling gaps between adjacent interconnection pillars and adjacent solder pads, and the first sealing layer exposing a top of the interconnection pillars; and
wherein when bonding the second substrate to the backside of the chip bridge, the second substrate is also bonded to the first sealing layer; and when forming the redistribution layer on the frontside of the chip bridge, the redistribution layer covers the first sealing layer.

12. The packaging method according to claim 11, wherein forming the first sealing layer on the first substrate comprises:
forming a first sealing material layer on the first substrate to fill the gaps between the adjacent interconnection pillars and the adjacent solder pads, the first sealing material layer covering the interconnection pillars and the chip bridge; and
planarizing the first sealing material layer until the top of the interconnection pillar is exposed to form the first sealing layer.

13. The packaging method according to claim 8, wherein the redistribution layer includes one or more stacked interconnection layers, an interconnection layer includes an interconnect via and an interconnection metal layer on the interconnect via, and the interconnect via is in contact with the chip bridge.

14. The packaging method according to claim 8, wherein bonding the chip structure and the first chip on the redistribution layer includes:
forming conductive bumps on the redistribution layer; or on both the first chip and the chip structure; and
bonding the chip structure and the first chip to the redistribution layer using the conductive bumps.

15. The packaging method according to claim 14, further comprising: forming the second sealing layer between adjacent conductive bumps, wherein the second sealing layer covers around the conductive bumps.

16. The packaging method according to claim 8, wherein the first chip comprises a logic chip, the chip structure comprises one or more second chips stacked in a vertical direction, and the second chip comprises a memory chip.
